(19) United States
(12) Patent Application Publication
(10) Pub. No.: US 2011/0212625 A1
(43) Pub. Date: Sep. 1, 2011

(54) SUBSTRATE PROCESSING APPARATUS AND METHOD OF MANUFACTURING SEMICONDUCTOR DEVICE

(75) Inventors: Kazuyuki TOYODA, Toyama-shi (JP); Osamu KASAHARA, Toyama-shi (JP); Yoshiro HIROSE, Toyama-shi (JP); Hiroyuki TAKADERA, Toyama-shi (JP); Daigi KAMIMURA, Toyama-shi (JP)

(73) Assignee: HITACHI KOKUSAI ELECTRIC INC., Tokyo (JP)

(21) Appl. No.: 13/035,112

(22) Filed: Feb. 25, 2011

(30) Foreign Application Priority Data
Feb. 26, 2010 (JP) 2010-041576
Mar. 24, 2010 (JP) 2010-067880
Jan. 5, 2011 (JP) 2011-000515

(51) Int. Cl. H01L 21/30; C23C 16/50; C23C 16/455; C23C 16/458

(52) U.S. Cl. 438/758; 118/723 R; 118/729; 118/730; 257/E21.211

(57) ABSTRACT

A substrate processing apparatus which is capable of improving a manufacture yield while processing a substrate with high precision, and a method of manufacturing a semiconductor device. The substrate processing apparatus includes a substrate support part provided within a process chamber and configured to support a substrate; a substrate support moving mechanism configured to move the substrate support part; a gas feeding part configured to feed a gas into the process chamber; an exhaust part configured to exhaust the gas within the process chamber; and a plasma generating part disposed to face the substrate support part.

### CROSS-REFERENCE TO RELATED APPLICATIONS

This application is based upon and claims the benefit of priority from Japanese Patent Application No. 2010-041576, filed on Feb. 26, 2010, Japanese Patent Application No. 2010-067880, filed on Mar. 24, 2010, and Japanese Patent Application No. 2011-000515, filed on Jan. 5, 2011, the entire contents of which are incorporated herein by reference.

### TECHNICAL FIELD

The present disclosure relates to a substrate processing apparatus which forms a thin film on a substrate, modifies a film formed on a substrate, etc., and a method of manufacturing a semiconductor device.

### BACKGROUND

As an example of a so-called batch apparatus which processes a plurality of substrates in batches, there is known a vertical substrate processing apparatus which vertically stacks and processes a plurality of substrates in batches (see Japanese Patent Laid-Open Publication No. 2006-156695). Also, in the related art, there is known a substrate processing apparatus which loads a plurality of substrates on a substrate support in a processing chamber and processes the substrates one by one (see Japanese Patent Laid-Open Publication No. H11-288798).

A single wafer apparatus for processing a single substrate (or wafer) has been known as one example of substrate processing apparatuses. It is known that the single wafer apparatus may process substrates with high precision because it processes the substrates one by one. In addition, as the size of a wafer increases nowadays, from a standpoint of apparatus durability, a single wafer apparatus is considered preferable rather than a batch apparatus which stacks and processes a plurality of substrates.

However, the single wafer apparatus has a problem of poor manufacture yield because it processes substrates one by one.

### SUMMARY

It is an object of some embodiments of the present disclosure to provide a substrate processing apparatus which is capable of increasing a manufacture yield while processing a substrate with high precision, and a method of manufacturing a semiconductor device.

To achieve the above object, according to an exemplary embodiment of the present disclosure, there is provided a substrate processing apparatus including: a substrate support part provided within a process chamber and configured to support a substrate; a substrate support moving mechanism configured to move the substrate support part; a gas feeding part configured to feed a gas into the process chamber; an exhaust part configured to exhaust the gas within the process chamber; and a plasma generating part provided to face the substrate support.

According to another exemplary embodiment of the present disclosure, there is provided a method of manufacturing a semiconductor device using a substrate processing apparatus including: a substrate support part provided within a process chamber and configured to support a substrate; a substrate support moving mechanism configured to move the substrate support part; a gas feeding part configured to feed a gas into the process chamber; an exhaust part configured to exhaust the gas within the process chamber; and a plasma generating part provided to face the substrate support part. The method includes: exhausting the gas from the exhaust part while feeding the gas from the gas feeding part; and moving the substrate support part during gas feeding/exhausting.

According to the substrate processing apparatus and the method of manufacturing a semiconductor device, it is possible to increase a manufacture yield while processing a substrate with high precision,

### BRIEF DESCRIPTION OF THE DRAWINGS

FIG. 1 is a plan view showing a substrate processing apparatus according to a first embodiment of the present disclosure.

FIG. 2 is a partially-omitted and cut perspective view of the substrate processing apparatus.

FIG. 3 is a partially-omitted side sectional view of the substrate processing apparatus.

FIG. 4 is a partially-omitted side sectional view showing a substrate processing apparatus according to a second embodiment of the present disclosure.

FIG. 5 is a partially-omitted side sectional view showing a substrate processing apparatus according to a third embodiment of the present disclosure.

FIG. 6 is a plan view showing a substrate processing apparatus according to a fourth embodiment of the present disclosure.

FIGS. 7A and 7B are a side view and a top view showing the substrate processing apparatus, respectively, according to the fourth embodiment of the present disclosure.

FIG. 8 is an enlarged view of a shower head according to the fourth embodiment of the present disclosure.

FIG. 9 is an explanatory view for explaining a case where wafers are loaded according to the fourth embodiment of the present disclosure.

FIG. 10 is an explanatory view for explaining an exhaust part of the substrate processing apparatus according to the fourth embodiment of the present disclosure.

FIGS. 11A and 11B are explanatory views for explaining a flow of gas in the substrate processing apparatus according to the fourth embodiment of the present disclosure.

FIGS. 12A and 12B are a side view and a top view showing a substrate processing apparatus, respectively, according to a fifth embodiment of the present disclosure.

FIGS. 13A to 13C are explanatory views for explaining a plasma source and its peripherals according to a fifth embodiment of the present disclosure.

FIG. 14 is a plan view showing a substrate processing apparatus according to a sixth embodiment of the present disclosure.

FIGS. 15A and 15B are a side view and a top view showing a substrate processing apparatus, respectively, as a comparative example.

FIG. 16 is an explanatory view for explaining a case where wafers are loaded, as a comparative example.

FIG. 17 is an explanatory view for explaining an exhaust part of a substrate processing apparatus, as a comparative example.

### DETAILED DESCRIPTION

Hereinafter, a first embodiment of the present disclosure will be described with reference to the drawings.

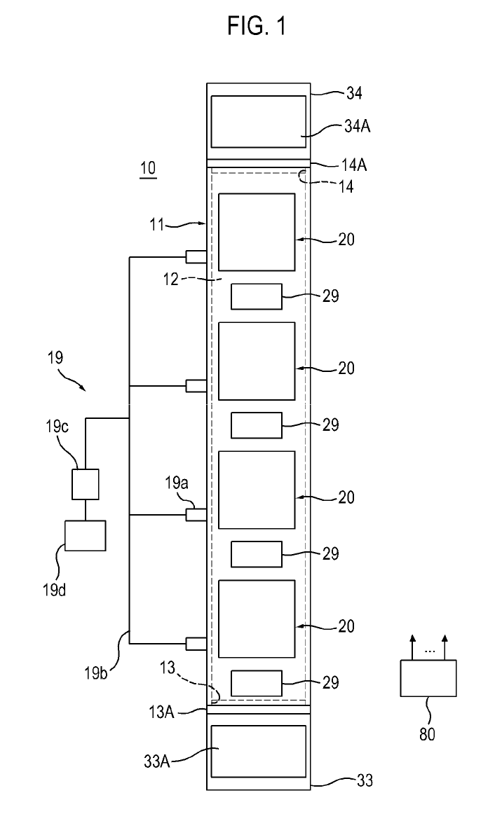

FIGS. 1 to 3 illustrate a first embodiment of the present disclosure. In this embodiment, a substrate processing apparatus 10 is configured to perform plasma process for a semiconductor wafer 18 (hereinafter referred to as “wafer 18”) which is a substrate on which semiconductor integrated circuit devices (hereinafter referred to as “semiconductor devices”) are formed in a method of manufacturing the semiconductor devices.

In this embodiment, the substrate processing apparatus 10 includes a housing 11 forming a processing chamber 12. The housing 11 has a rectangular tubular shape, where the processing chamber 12 is formed in a tubular hollow part thereof.

An entrance 13 is formed in an opening in the front wall of the housing 11, and an exit 14 is formed in an opening in a wall of the housing 11 which faces the entrance 13. The entrance 13 is configured to be opened/closed by a gate 13A, and the exit 14 is configured to be opened/closed by a gate 14A.

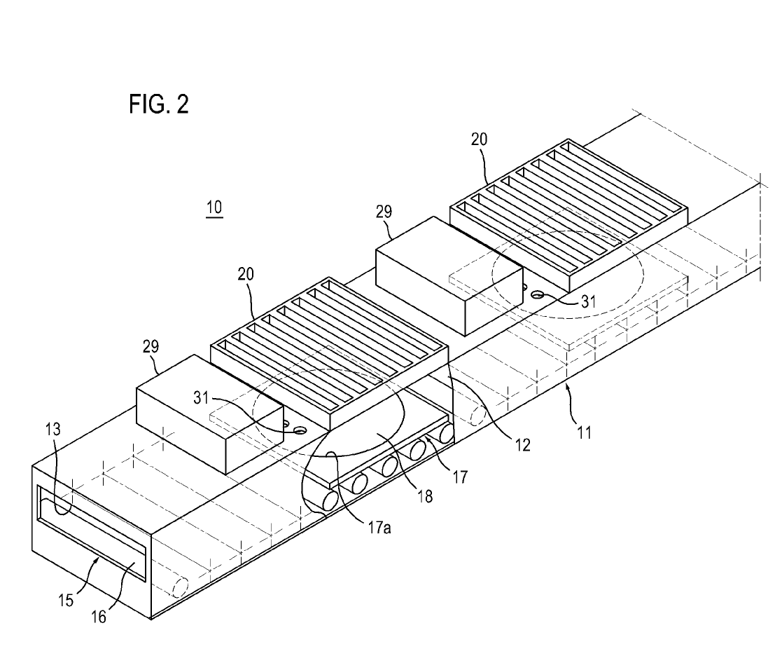

As shown in FIG. 1, an entrance side preliminary chamber 33 is connected to the front wall of the housing 11 in which the entrance 13 is formed, and an exit side preliminary chamber 34 is connected to the other wall in which exit 14 is formed. Both preliminary chambers 33 and 34 are configured to be decompressable. A preliminary chamber heater 33A is provided in the entrance side preliminary chamber 33 and is configured to heat the wafer 18 before it enters the housing 11. In addition, a preliminary chamber cooler 34A is provided in the exit side preliminary chamber 34 and is configured to cool the wafer 18 heated in the housing 11. For the sake of explanation, the preliminary chambers 33 and 34 are not shown in FIG. 2.

The substrate processing apparatus 10 includes a controller 80 configured to control various components of the substrate processing apparatus 10.

Within the processing chamber 12 is a horizontally disposed conveyor 15, which is a substrate support moving mechanism configured to move a plurality of substrate holders 17 (substrate support parts, which will be described later) in a row at an interval, over the entire length of the chamber 12. The conveyor 15 includes a plurality of rotating rollers 16 and is configured to convey the substrate holders 17 supporting the wafers 18 (as movement or conveyance targets) according to the rotation of the rollers 16. The width of the conveyor 15 is set to be larger than the width of the substrate holders 17. In addition, the processing chamber 12 is set to have a length such that a plurality of substrate holders 17 (e.g., 4 substrate holders) can be conveyed in a row with the same pitch.

Each of the substrate holders 17 has a square plate shape and its outer width is set to be larger than a diameter of each wafer 18. The substrate holder 17 includes a fallen hold hole 17a formed in a surface (hereinafter referred to as a “top surface”) of the substrate holder 17, which does not face the rollers 16. The hold hole 17a accommodates the wafer 18 such that the wafer 18 is located and detachably held therein.

As shown in FIGS. 1 and 2, a plurality of plasma generators 20 (e.g., 4 plasma generators in this embodiment), each having a pair of electrodes, is arranged on a ceiling wall of the housing 11 with the same pitch in a conveyance direction of the conveyor 15 (hereinafter referred to as a “longitudinal direction”). Each plasma generator 20 has electrodes. While power is applied to the electrodes, a process gas supplied to the processing chamber 12 becomes plasma state, which will be described later.

Gas exhaust ports 19a for exhausting a gas in the processing chamber 12 are formed on one side wall of the processing chamber 12 and are connected to gas exhaust pipes 19b, respectively. The gas exhaust pipes 19b are provided to correspond to the plurality of plasma generators 20, respectively. The gas exhaust pipes 19b join at a downstream position, where a pressure regulating valve 19c and a vacuum pump 19d (as an exhauster) are serially provided. By adjusting the opening of the pressure regulating valve 19c, an internal pressure of the processing chamber 12 is regulated at a predetermined value.

The gas exhaust ports 19a, the gas exhaust pipes 19b, the pressure regulating valve 19c and the vacuum pump 19d constitutes a gas exhaust part 19 in this embodiment. The pressure regulating valve 19c and the vacuum pump 19d are electrically connected to the controller 80 to control the pressure regulation as explained above. For the sake of explanation, the gas exhaust part 19 is not shown in FIG. 2.

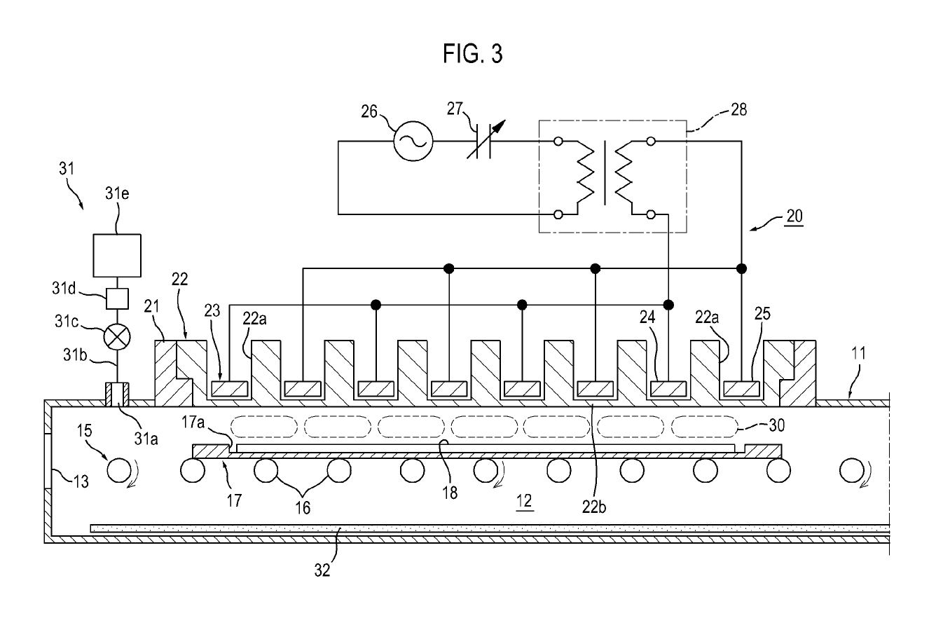

As shown in FIG. 3, the plasma generator 20 according to the present embodiment includes a square frame-shaped bracket 21, which may be made of an insulating material. The bracket 21 is densely packed and fixed on the ceiling wall of the housing 11 and a holder 22 is inserted within a frame of the bracket 21.

The holder 22 may be made of a dielectric material such as quartz (SiO₂) or the like and has a square plate shape. A plurality of rectangular elongated recesses 22a (8 recesses in the example as shown in FIG. 3) of a predetermined depth is formed on the top surface of the holder 22 with the same pitch in a direction perpendicular to the advancing direction of the substrate holders 17.

The plasma generator 20 includes a comb-shaped electrode pair as a pair 23 of electrodes. The comb-shaped electrode pair 23 includes a plurality of pairs of electrodes 24 and electrodes 25 (4 pairs of electrodes in this example). The electrode 24 and the electrode 25 each have a rectangular elongated plate shape and are accommodated in adjacent elongated recesses 22a and 22a, respectively. That is, the electrodes 24 and 25 are arranged in a direction perpendicular to the advancing direction of the wafer 18. Plasma 30 may be generated in an area between the electrodes 24 and 25 in an extending direction thereof.

By arranging the electrodes 24 and 25 perpendicular to the advancing direction of the wafer 18, a surface of the wafer 18 can be scanned with the generated plasma 30. Accordingly, the plasma 30 can be uniformly exposed on the wafer 18. If the advancing direction of the wafer 18 is set in parallel to the extending direction of the electrodes 24 and 25, a film thickness of the wafer 18 may become uneven since the plasma 30 is generated on the wafer 18 in parallel to the advancing direction of the wafer 18.

The electrode 24 and the electrode 25 respectively accommodated in the elongated recesses 22a and 22a are separated from the processing chamber 12 by the bottom walls of the elongated recesses 22a. In this manner, since the holder 22 (which may be made of the dielectric material) is provided between the comb-shaped electrode pair 23 and the processing chamber 12, it is possible to prevent metallic contamination which may be caused by a piece of metal resulting from wear of the electrodes 24 and 25 caused by the plasma 30. In this case, the bottom walls 22b are set to be thick enough to generate the plasma 30 without disrupting formation of a thin film on the wafer 18.

A high frequency power supply 26 is connected to the plasma generator 20. Specifically, the high frequency power supply 26 is connected to the comb-shaped electrode pair 23 via a matching transformer 27 and an insulating transformer 28. That is, the high frequency power supply 26 is connected to a primary side of the insulating transformer 28 via the matching transformer 27, and the comb-shaped electrode pair 23 is connected to a secondary side of the insulating transformer 28. The plurality of pairs of electrodes 24 and electrode 25 of the comb-shaped electrode pair 23 is connected in parallel to the insulating transformer 28.

The high frequency power supply 26, the matching transformer 27 and the insulating transformer 28 are contained in a distributing board 29 disposed on the ceiling wall of the housing 11 (see FIGS. 1 and 2). The plasma generator 20, the high frequency power supply 26, the matching transformer 27 and the insulating transformer 28 are hereinafter collectively referred to as a plasma generating part.

In this embodiment, adjacent plasma generating parts arranged along a direction from the entrance 13 to the exit 14 are respectively referred to as a first plasma generating part, a second plasma generating part, a third plasma generating part, etc. Likewise, adjacent plasma generators arranged along a direction from the entrance 13 to the exit 14 are respectively referred to as a first plasma generator, a second plasma generator, a third plasma generator, etc.

A surface of the bottom wall 22b, which faces the wafer 18, is provided substantially in parallel to the surface of the wafer 18. That is, the bottom wall 22b is configured to be substantially in parallel to the conveyor 15. This configuration enables the plasma 30 to be uniformly exposed on the wafer 18.

A gas feeding port 31a is formed on the ceiling wall of the housing 11 and is connected with one end of a gas feeding pipe 31b. The gas feeding pipe 31b is connected with a gas source 31e, a flow rate controller 31d for controlling a gas flow rate, and a valve 31c for switching a gas flow passage, which are sequentially arranged from the top. By performing a switching operation on the valve 31c, a gas is fed or cut off from the gas feeding pipe 31b into the processing chamber 12.

The gas feeding port 31a, the gas feeding pipe 31b, the valve 31c, the flow rate controller 31d and the gas source 31e constitute a gas feeding part 31. The flow rate controller 31d and the valve 31c are electrically connected to and controlled by the controller 80.

A heater 32 is disposed on the bottom of the housing 11. The heater 32 heats the wafer 18 and the substrate holder 17 conveyed by the conveyor 15.

Operation and effects of the substrate processing apparatus 10 as configured above will be described below. Operation of various components is controlled by the controller 80.

The substrate holder 17 on which the wafer 18 is loaded is introduced into the entrance side preliminary chamber 33. In the entrance side preliminary chamber 33, a preliminary chamber heater 33A heats the substrate holder 17 and the wafer 18. While these components are being heated, the entrance side preliminary chamber 33 is set to have substantially the same pressure as the housing 11. In addition, the internal pressure of the housing 11 is kept constant by cooperation of the gas exhaust part 19 and the gas feeding part 31.

After the wafer 18 is heated to reach a predetermined temperature, the gate 13A is opened and the substrate holder 17 is loaded on the conveyor 15. After the substrate holder 17 is loaded, the gate 13A is closed, thereby partitioning the housing 11 and the entrance side preliminary chamber 33.

A substrate holder 17 holding the wafer 18 in advance is introduced through the entrance 14 and loaded on the conveyor 15. The substrate holder 17 is loaded on the conveyor 15 and the wafer 18 mounted on the substrate holder 17 are heated by the heater 32 until the temperature thereof reaches a preset processing temperature.

The conveyor 15 conveys the first substrate holder 17 and stops the conveyance when the substrate holder 17 to be first processed (the first substrate holder 17) faces one plasma generator 20 (a first plasma generator 20). In this state, as shown in FIG. 3, gas is supplied from the gas feeding part 31 and then the plasma generator 20 generates plasma 30 above the substrate holder 17 to perform plasma process on the wafer 18. At this time, the next second substrate holder 17 is ready in the entrance side preliminary chamber 33.

After a predetermined period of processing time elapses, the second substrate holder 17 is conveyed from the entrance side preliminary chamber 33 to the housing 11. At this time, the second substrate holder 17 is loaded on the conveyor in such a manner that a distance between the first substrate holder 17 and the second substrate holder 17 is equal to a distance between the first plasma generator 20 and the second plasma generator 20.

The conveyor 15 conveys the first substrate holder 17 such that the first substrate holder 17 faces the second plasma generator 20. In addition, the conveyor 15 conveys the first substrate holder 17 and the second substrate holder 17 such that the second substrate holder 17 faces the first plasma generator 20. At this time, a third substrate holder 17 is loaded in the entrance side preliminary chamber 33.

In this manner, the substrate holders 17 are sequentially conveyed and the wafers 18 are subject to plasma process under the respective plasma generators 20. Such sequential process by the respective plasma generators 20 allows the wafers 18 to be deposited to have a desired film thickness.

A wafer 18 on which plasma process is completed under the plasma generator 20, which is arranged closest to the exist 14, is exported from the housing 11 as follows. First, the gate 14A of the exit 14 is opened after the wafer 18 is processed for a predetermined time under the plasma generator 20 closest to the exit 14. When the gate 14A is opened, the wafer 18 is exported to the exit side preliminary chamber 34 by means of a conveyance mechanism (not shown). After the wafer 18 is exported, the gate 14A is closed.

The conveyed substrate holder 17 is cooled by means of the preliminary chamber cooler 34A in the exit side preliminary chamber 34. At the same time, the wafer 18 is cooled. By doing so, since the wafer 18 can be quickly cooled, the wafer 18 can be transferred and loaded into a different apparatus which may not process a hot wafer 18.

However, for example if the plasma generator includes a substrate holder configured using capacitively-coupled flat plate electrodes, one of which continues to move, the following problem may arise. If the wafer 18 is subjected to the plasma process while continuously moving the substrate holder holding the wafer 18, this causes an upper electrode to be deviated from a lower electrode. This in turn causes a variation of formation states (volume, density, electron temperature, etc.) of plasma being generated, and thus, the wafer 18 cannot be uniformly subjected to the plasma process.

In this embodiment, since the plasma 30 can be generated by the electrodes of the plasma generator 20 without being affected by the wafer 18, the substrate holder 17, the conveyor 15, etc., the plasma formation states are not affected even when the substrate holder 17 holding the wafer 18 is continuously moved by the conveyor 15. Accordingly, the wafer 18 can be uniformly subjected to the plasma process even when the substrate holder 17 is continuously moved by the conveyor 15. In addition, since a plurality of wafers 18 can be continuously processed in the housing 11, it is possible to achieve a high manufacture yield as compared to conventional single wafer apparatuses.

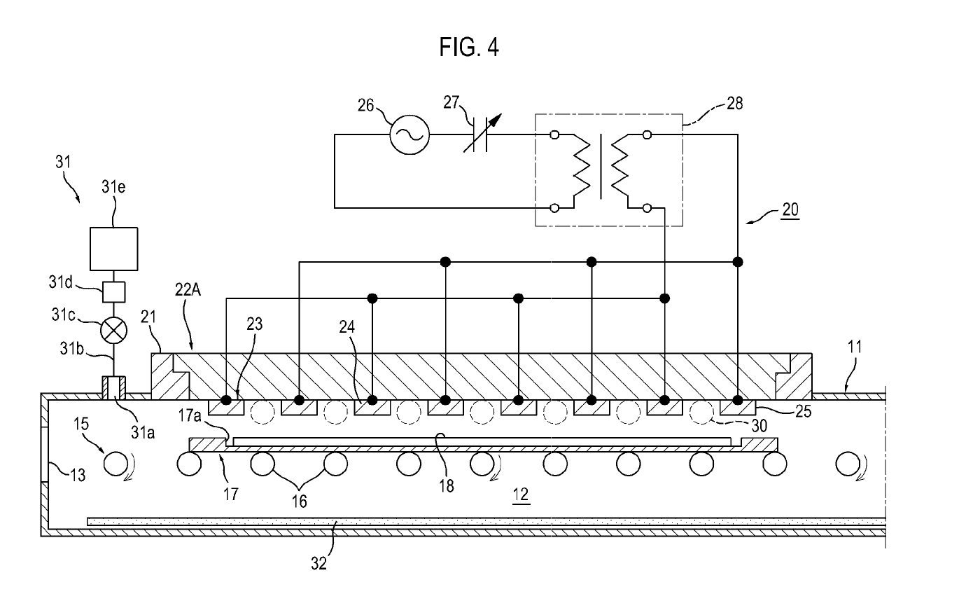

FIG. 4 shows a second embodiment of the present disclosure. This embodiment has the same configuration as the first embodiment except that a holder 22A holding the comb-shaped electrode pair 23 has a plate shape and the comb-shaped electrode pair 23 is disposed on one side of the holder 22A, which is an inner side of the processing chamber 12, so that it contacts the plasma 30.

In the second embodiment, the comb-shaped electrode pair 23 does not pass through a dielectric such as quartz or the like. In other words, the comb-shaped electrode pair 23 communicates with the processing chamber 12. With this configuration, an electric field generated by the comb-shaped electrode pair 23 is better maintained as compared to the first embodiment having the bottom wall 22b. Accordingly, the second embodiment can generate the plasma 30 more efficiently than the first embodiment. However, if a corrosive gas is used as a gas to be fed, the comb-shaped electrode pair 23 may deteriorate or be etched. In this case, it is possible to extend the life span of the comb-shaped electrode pair 23 by constructing the comb-shaped electrode pair 23 using a material such as silicon carbide (SiC).

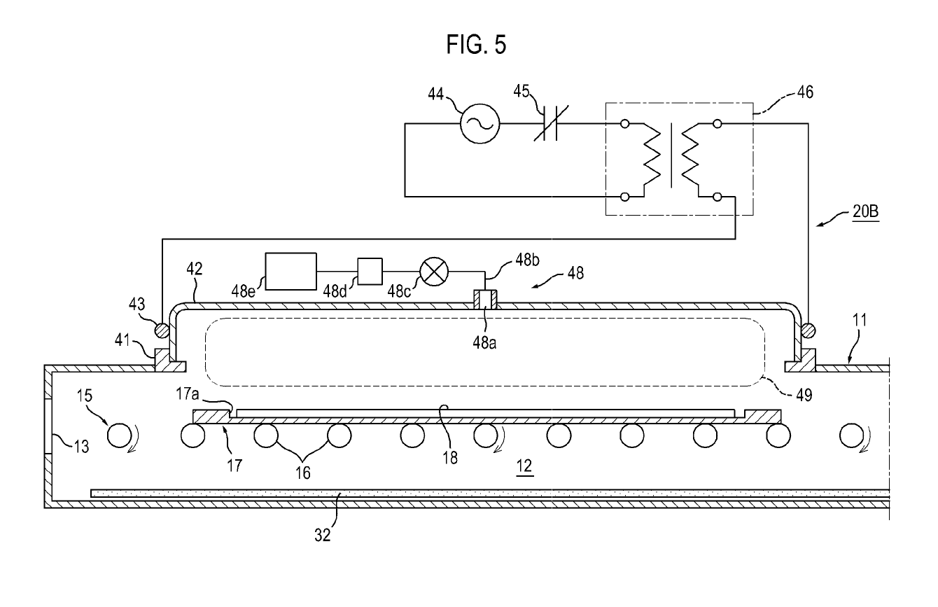

FIG. 5 shows a third embodiment of the present disclosure. This embodiment has the same configuration as the first embodiment except that a plasma generator equivalent to the plasma generator 20 is of an inductive coupling type (inductive coupling type device 20B).

Hereinafter, the inductive coupling type device 20B will be described with reference to FIG. 5. The inductive coupling type device 20B includes a bracket 41. The bracket 41 is fixedly assembled to the ceiling wall of the housing 11 and a dome 42 is inserted in the frame of the bracket 41. The dome 42 may be made of a nonmetallic material such as aluminum oxide, quartz or the like. A coil 43 is wound around the circumference of the dome 42 and a high frequency power supply 44 for applying high frequency power is connected to the coil 43 via a matching transformer 45 and an insulating transformer 46. The high frequency power supply 44, the matching transformer 45 and the insulating transformer 46 are contained in a distributing board (not shown) disposed on the ceiling wall of the housing 11.

The inductive coupling type device 20B, the coil 43, the high frequency power supply 44, the matching transformer 45 and the insulating transformer 46 constitute a plasma generating part. Plasma 49 is generated by applying high frequency power to the coil 43.

A gas feeding port 48a is formed on a ceiling wall of the dome 42 and is connected to one end of a gas feeding pipe 48b. The gas feeding pipe 48b is connected to a gas source 48e, a flow rate controller 48d for controlling a gas flow rate, and a valve 48c for switching a gas flow passage, which are arranged in order from the top. By performing a switching operation of the valve 48c, gas is fed or cut off from the gas feeding pipe 48b into the processing chamber 12.

The gas feeding port 48a, the gas feeding pipe 48b, the valve 48c, the flow rate controller 48d and the gas source 48e form a gas feeding part 48. The flow rate controller 48d and the valve 48c are electrically connected to and controlled by the controller 80.

Also in this embodiment, since the plasma 49 can be generated by the inductive coupling type device 20B without being affected by the wafer 18, the substrate holder 17, the conveyor 15, etc., the plasma formation states are not affected even when the substrate holder 17 holding the wafer 18 is continuously moved by the conveyor 15. Accordingly, the wafer 18 can be uniformly subjected to the plasma process even when the substrate holder 17 is continuously moved by the conveyor 15. In addition, since a plurality of wafers 18 can be continuously processed in the housing 11, it is possible to achieve a high manufacture yield as compared to conventional signal wafer apparatuses.

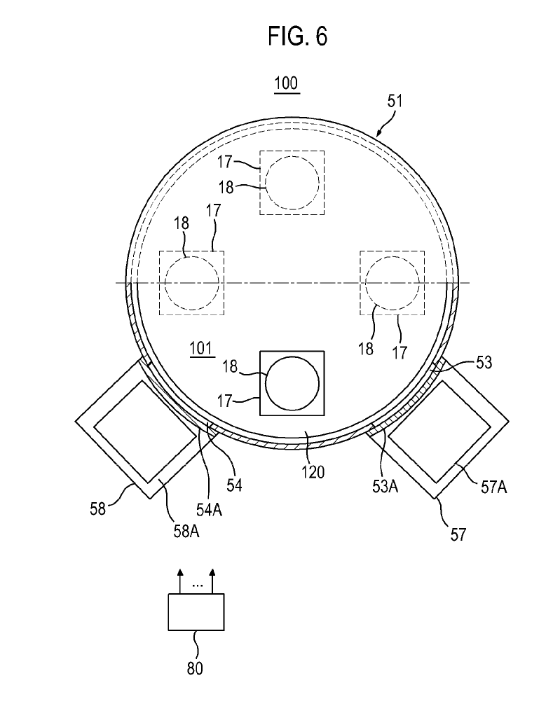

FIGS. 6 to 11 show a fourth embodiment of the present disclosure. This embodiment is different from the first embodiment in that the substrate processing apparatus is of a rotary type.

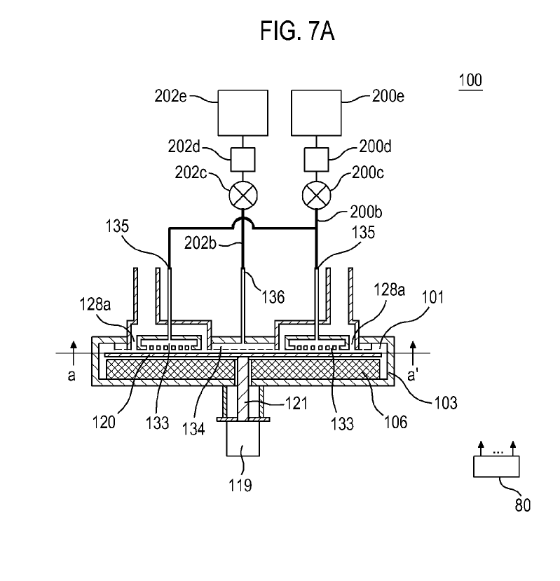

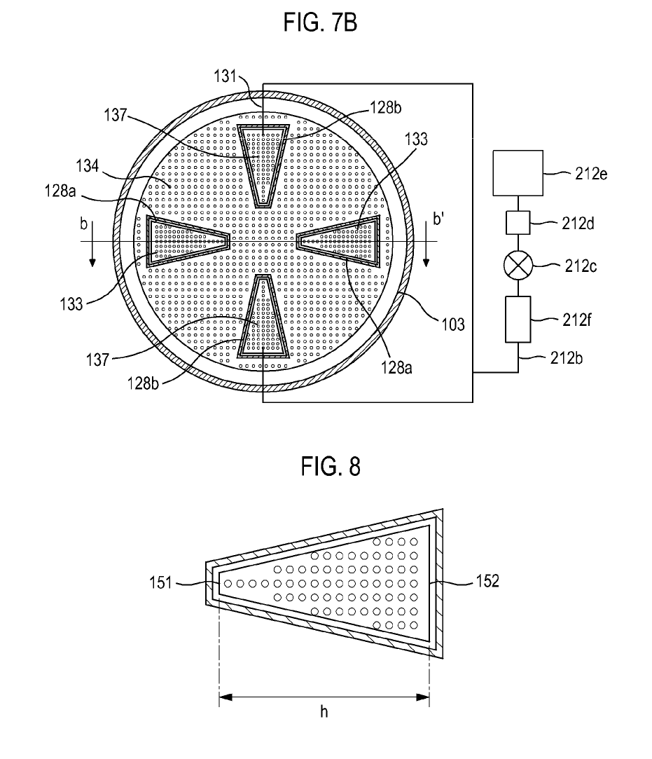

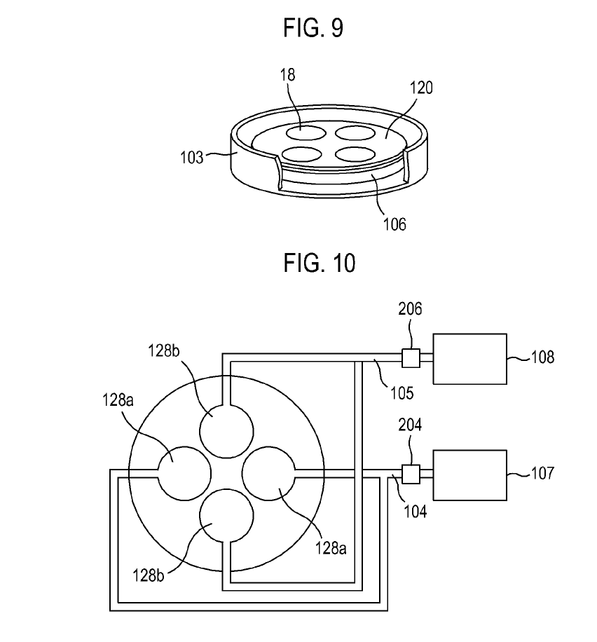

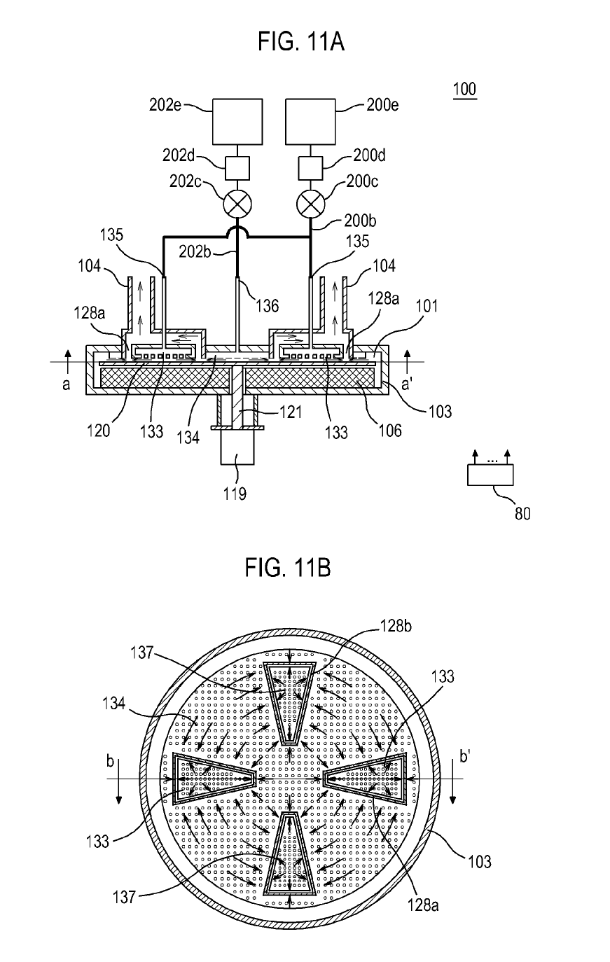

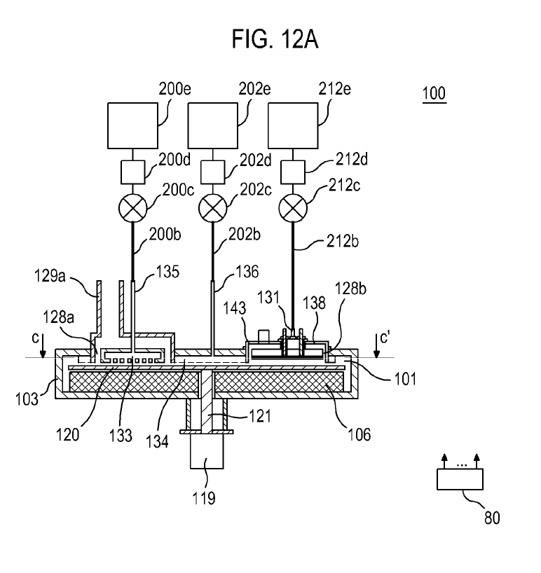

First, a substrate processing apparatus 100 according to this embodiment will be described. FIG. 6 is a partially cut plan view of the substrate processing apparatus 100 according to the fourth embodiment. FIG. 7A is a side sectional view of the substrate processing apparatus 100 according to this embodiment. FIG. 7B is a view taken in a direction indicated by an arrow a-a′ in FIG. 7A. In addition, FIG. 7A is a view taken in a direction indicated by an arrow b-b′ in FIG. 7B. FIG. 8 is an enlarged view of a first shower head 133 (or second shower head 137). FIG. 9 is an explanatory view for explaining a case where the wafers 18 are loaded. FIG. 10 is an explanatory view for explaining an exhaust part of the substrate processing apparatus 100. FIG. 11 is an explanatory view for explaining a gas flow of the substrate processing apparatus 100.

In this embodiment, the substrate processing apparatus 100 includes a housing 51 forming a processing chamber 101. The housing 51 has a cylindrical shape and the processing chamber 101 is formed in a cylindrical hollow portion thereof. The processing chamber 101 is surrounded by a circular reaction chamber wall 103. An entrance 53 and an exit 54 are formed adjacent to each other on a side wall of the housing 51. The entrance 53 is configured to be opened/closed by a gate 53A, while the exit 54 is configured to be opened/closed by a gate 54A.

An entrance side preliminary chamber 57 is connected to a wall of the housing 51 in which the entrance 53 is formed, while an exit side preliminary chamber 58 is connected to the other wall in which the exit 54 is formed. Both preliminary chambers 57 and 58 are configured to be decompressable. A preliminary chamber heater 57A is provided in the entrance side preliminary chamber 57 and is configured to heat the wafer 18 before it enters the housing 51. In addition, a preliminary chamber cooler 58A is provided in the exit side preliminary chamber 58 and is configured to cool the wafer 18 heated in the housing 51.

Within the processing chamber 101 is a horizontally disposed rotating tray 120, which is a substrate support moving mechanism which moves a plurality of substrate holders 17 (substrate support parts) in a row at an interval. A heater 106 for heating the wafer 18 is arranged on the bottom of the processing chamber 101 and the rotating tray 120 is arranged on the top of the heater 106. In addition, the rotating tray 120 is connected to a rotation driver 119. The rotating tray 120 is rotated as the rotation driver 119 rotates a shaft 121.

In a space above a wafer loading surface of the rotating tray 120 are contained a process gas feeding part for feeding a process gas, an inert gas feeding part for feeding an inert gas, and an exhaust part.

As shown in FIG. 7, a first gas feeding part includes a first shower head 133 having a plurality of feeding holes, a first gas introduction port 135, a gas feeding pipe 200b, a valve 200c for switching a gas flow passage, a flow rate controller 200d for controlling a gas flow rate and a gas source 200e. The gas feeding pipe 200b is connected to the first gas introduction port 135. In addition, the gas feeding pipe 200b is connected to the gas source 200e, the flow rate controller 200d and the valve 200c, which are arranged in order from the top. By performing a switching operation of the valve 200c, gas is fed or cut off from the gas feeding pipe 200b into the processing chamber 101. The first gas feeding part feeds a first process gas, for example, dichlorosilane (DCS).

A second gas feeding part includes a second shower head 137 having a plurality of feeding holes, a second gas introduction port 131, a gas feeding pipe 212b, a valve 212c for switching a gas flow passage, a flow rate controller 212d for controlling a gas flow rate and a gas source 212e. The gas feeding pipe 212b is connected to the second gas introduction port 131. In addition, the gas feeding pipe 212b is connected to the gas source 212e, the flow rate controller 212d, the valve 212c and a remote plasma mechanism 212f, which are arranged in order from the top. By performing a switching operation of the valve 212c, a gas is fed or cut off from the gas feeding pipe 212b into the processing chamber 101. The second gas feeding part feeds a second process gas, for example, an ammonia gas. In this embodiment, the second gas feeding part feeds ammonia radicals activated by the remote plasma mechanism 212f.

First exhaust holes 128a are formed to surround the first shower head 133. In addition, like the first shower head 133, the first exhaust holes 128a are arranged in the space above the wafer loading surface of the rotating tray 120 (upward with respect to the gravity direction).

As shown in FIG. 10, the first exhaust holes 128a are connected to a first exhaust pipe 104 which is a first exhaust passage. The first exhaust pipe 104 is connected to a first exhaust pump 107, which is a first exhauster part, via a first pressure regulating valve (APC valve) 204. The first exhaust holes 128a, the first exhaust pipe 104, the first exhaust pump 107 and the first APC valve 204 are collectively referred to as a first exhaust part.

Likewise, second exhaust holes 128b are formed to surround the second shower head 137. In addition, like the second shower head 137, the second exhaust holes 128b are arranged in the space above the wafer loading surface of the rotating tray 120 (upward with respect to the gravity direction).

As shown in FIG. 10, the second exhaust holes 128b are connected to a second exhaust pipe 105 which is a second exhaust passage separate from the first exhaust passage. The second exhaust pipe 105 is connected to a second exhaust pump 108, which is a second exhaust part, via a second pressure regulating valve (APC valve) 206. The second exhaust holes 128b, the second exhaust pipe 105, the second exhaust pump 108 and the second APC valve 206 are collectively referred to as a second exhaust part.

As shown in FIG. 8, a gas feeding surface of each of the shower heads 133 and 137 has a trapezoidal shape in such a manner that the lower bottom 152 provided farther from the shaft 121 of the rotating tray 120 is longer than the upper bottom 151 provided closer to the shaft 121. Gas feeding holes formed in the gas feeding surface are increasingly formed from the upper bottom 151 to the lower bottom 152. With this configuration, the time required for exposing gas from the lower bottom 152 side with respect to the wafer 18 may be approximately the same amount of time required for exposing gas from the upper bottom 151. Such times are in some embodiments preferably equalized by adjusting the number of holes at the lower bottom 152 and the upper bottom 151.

In this embodiment, when the wafer 18 is rotated around the shaft 121, a spot (point) on the surface of the wafer 18 farther from the shaft 121 is rotated at a higher speed. That is, there is a difference in rotation speed between a point on the wafer 18 closer to the shaft 121 and a point on the wafer 18 farther from the shaft 12. With this structure, the amount of feed of gas with respect to the wafer 18 at points thereon closer to the shaft 121 may approximate the amount of feed of gas with respect to the wafer 18 at points thereon farther from the shaft 121, thereby allowing uniform processing (for example, absorption) on the surface of the wafer 18.

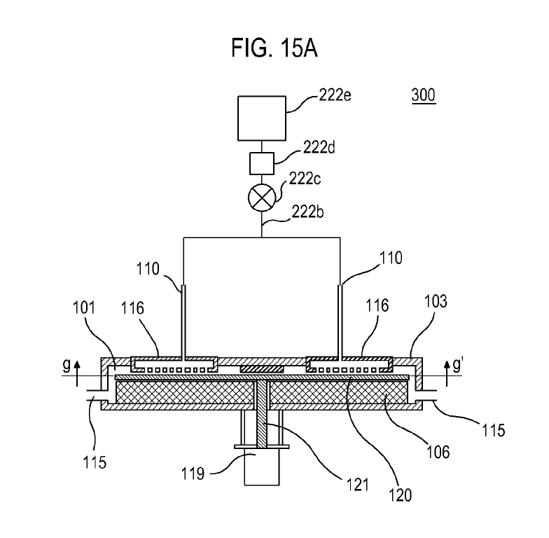

Consider an apparatus where points on the wafer 18 closer to the shaft 121 have the same amount of gas feed as points on the wafer 18 farther from the shaft 121, as in a comparative example of FIGS. 15A and 15B. Further, consider a case where absorption process is performed as substrate process. In this case, by rotating the wafer 18 at such a speed that gas is uniformly absorbed at points far away from the shaft 121, the gas can be uniformly absorbed on the surface of the wafer 18. This is because the gas is uniformly absorbed due to a self-limiting effect even when time for which gas is fed to the wafer 18 is prolonged. As used herein, the “self-limiting effect” refers to a state where a film cannot be grown any more even under a process gas atmosphere. However, the adjustment of the speed of the wafer 18 such that gas is uniformly absorbed at points far away from the shaft 121 may result in a low manufacture yield. The structure of this embodiment can provide a process with a higher manufacture yield.

A distance (h) between the upper bottom 151 and the lower bottom 152 (i.e., a distance corresponding to the height of the trapezoid) is set to be equal to or larger than the diameter of the wafer 18. With this structure, it is possible to reliably feed gas onto the surface of the wafer 18 on the rotating tray 120.

The inert gas feeding part includes a shower plate 134 formed between first and second gas exhaust holes 128a and 128b, a gas introduction port 136, a gas feeding pipe 202b, a valve 202c for switching a gas flow passage, a flow rate controller 202d for controlling a gas flow rate and a gas source 202e. The gas feeding pipe 202b is connected to the gas introduction port 136. In addition, the gas feeding pipe 202b is connected to the gas source 202e, the flow rate controller 202d and the valve 202c, which are arranged in order from the top. By performing a switching operation of the valve 202c, a gas is fed or cut off from the gas feeding pipe 202b into the processing chamber 101. The shower plate 134 uniformly supplies an inert gas (for example, nitrogen) fed from the gas introduction port 136.

In this manner, the shower plate 134, the gas introduction port 136, the gas feeding pipe 202b, the valve 202c for switching a gas flow passage, the flow rate controller 202d for controlling a gas flow rate and the gas source 202e constitute the inert gas feeding part as a third gas feeding part.

The first shower head 133, the second shower head 137 and the shower plate 134 are arranged as shown in FIG. 7B. That is, the first shower head 133 and the second shower head 137 are horizontally alternately arranged around the shaft 121 of the rotating tray 120 (i.e., alternately arranged with respect to a rotation direction of the shaft 121). In addition, the shower plate 134 is arranged to form gaps in the exhaust holes 128a and 128b.

The rotation driver 119, the gas feeding part, the exhaust part and so on are electrically connected to the controller 80 to control these components.

Next, as one step of a process of manufacturing a semiconductor device according to this embodiment which is performed by the above-described substrate processing apparatus 100, an example sequence of forming an insulating film on a substrate will be described. As described below, operation of various components of the above-described semiconductor manufacturing apparatus is controlled by the controller 80.

It is here assumed that a first element is silicon (Si) and a second element is nitrogen (N). An example of forming a silicon nitride film (SiN film) as an insulating film on the wafer 18 using a dichlorosilane (DCS) gas (first gas), which is a silicon containing gas used as a process gas containing the first element, and an ammonia (NH₃) gas (second gas), which is a silicon containing gas used as a process gas containing the second element, will be described.

(Wafer Import Step): First, the gate 53A of the entrance 53 is opened, and a plurality of wafers 18 (four wafers in this example) are imported into the processing chamber 101 by means of a conveyance device (not shown) and are loaded on the rotating tray 120 around the shaft 121. Then, the gate 53A is closed.

(Pressure Regulating Step): Next, the first and second exhaust pumps 107 and 108 are actuated and a degree of opening of the first and second APC valves 204 and 206 is regulated until the atmosphere of the processing chamber 101 has a predetermined pressure (film formation pressure). In addition, power is applied to the heater 106 and a temperature (film formation temperature) of the wafer 18 is controlled to be kept at a predetermined temperature (for example, 350° C.). In addition, an inert gas (nitrogen in this example) is fed from the shower plate 134 while rotating the rotating tray 120 at a rate of one revolution/sec during the heating.

(Film Formation Step): While the rotating tray 120 is rotated, the first process gas, i.e., DCS, is fed from the first shower head 133 into the processing chamber 101. When the DCS gas is fed, a first layer containing silicon as the first element is formed (chemically absorbed) on an underlying film (base film) of the surface of the wafer 18 passing below the first shower head 133. That is, a silicon layer (Si layer) as a silicon containing layer having less than one atomic layer or one to several atomic layers is formed on the wafer 18 (underlying film). The silicon containing layer may be a DCS chemical absorption layer (or a surface absorption layer). Silicon is an element having a solid state solely.

As used therein, the phrase “silicon containing layer” is intended to include a continuous layer or a discontinuous layer formed by silicon or a thin film including a stack thereof. In some cases, the continuous layer formed by silicon may be referred to as a thin film. In addition, as used therein, the phrase “DCS chemical absorption layer” is intended to include a discontinuous chemical absorption layer in addition to a continuous chemical absorption layer of DCS molecules.

In addition, if a thickness of the silicon containing layer formed on the wafer 18 exceeds several atomic layers, a nitrification may not be exerted on the entire silicon containing layer in a subsequent nitrification process. In addition, the minimal thickness of the silicon containing layer which can be formed in the wafer 18 is less than one atomic layer. Accordingly, the thickness of the silicon containing layer is, in some embodiments, preferably set to be less than one to several atomic layers.

In addition, conditions such as the temperature of the wafer, the internal pressure of the processing chamber 101 and so on may be controlled such that a silicon layer is formed by depositing silicon on the wafer 18 under a condition where the DCS gas is self-decomposed. Under the above conditions, a DCS chemical absorption layer is formed by chemically absorbing DCS on the wafer 18 under a condition where the DCS gas is not self-decomposed.

In addition, ammonia as the second process gas is fed from the second shower head 137 in a state activated by the remote plasma mechanism 212f (i.e., in a radical state). A flow rate of the ammonia gas is controlled by the flow rate controller 212d. A NH₃ gas has low reactivity under the temperature of the wafer and the internal pressure of the processing chamber, adjusted as described above, due to its high reaction temperature. Therefore, a NH₃ gas flows out after it is plasma-excited into radicals. Accordingly, the wafer 18 is in some embodiments preferably set to have a range of low temperature as described above. Thus, there is no need to change the temperature of the heater 106.

In addition, the NH₃ gas may be thermally activated by non-plasma by setting the temperature of the wafer 18 to be, for example, 600° C. or more by properly adjusting the temperature of the heater 106 and setting the internal pressure of the processing chamber 101 to fall within, for example, a range of 50 to 3000 Pa by properly adjusting the second APC valve 206 without plasma excitation of the NH₃ gas to be fed. In addition, when the NH₃ gas is thermally activated and fed, a soft reaction may be caused, which requires high temperature.

Accordingly, thermal activation is not suitable for processing of the wafer which is vulnerable to high temperature treatment. As used therein, the phrase “wafer vulnerable to high temperature treatment” may refer to a wafer having wirings including aluminum or the like. For such a wafer, wirings are prone to be oxidized or modified. In addition, since the processing temperature (wafer temperature) by the first processing gas increases, it should be considered that the wafer temperature may exceed a predetermined range of temperature by the processing by the first processing gas. Thus, when a thermally activated gas is used, it is in some embodiments preferable that the wafer is tolerable to high temperature processing and the processing by the first processing gas may be performed at high temperatures.

On the other hand, gas activation by the plasma generating part has the following advantage. That is, if the temperature of the wafer processed by the first processing gas is different from that of the wafer processed by the second processing gas, the heater 106 may be controlled to adjust its temperature to a temperature that is lower than one of the above temperatures of the wafer. Thus, even a wafer vulnerable to the high temperature can be processed.

The silicon containing layer as the first layer is formed on the wafer 18 as it moves from below the first shower head 133 to below the second shower head 137. In this case, the NH₃ gas as radicals reacts with a portion of the silicon containing layer. According to this reaction, the silicon containing layer is nitrified to be modified into a second layer containing silicon (the first element) and nitrogen (the second element), i.e., a silicon nitride layer (SiN layer). The process performed in this manner, i.e., to form the silicon nitride layer when the wafer 18 passes below the first shower head 133 and the second shower head 137 is referred to as a silicon nitride layer forming process.

When the wafer 18 is rotated along with the rotating tray 120, the wafer 18 passes below the first shower head 133 and the second shower head 137 and subsequently passes below another first shower head 133 and another second shower head 137. In this manner, a silicon nitride layer can be formed with a predetermined thickness by repeating the silicon nitride layer forming process on the wafer 18.

Subsequently, a flow of gas to be fed will be described with reference to FIGS. 10 and 11. The DCS gas fed from the first shower head 133 is exposed on the wafer 18 and then is exhausted from the first exhaust holes 128a along with the inert gas fed from the shower plate 134. In addition, the NH₃ gas fed from the second shower head 137 is exposed on the wafer 18 and then is exhausted from the second exhaust holes 128b along with the inert gas fed from the shower plate 134.

Since the inert gas fed from the shower plate 134 exists between the DCS gas exhausted from the first exhaust pipe 104 and the first exhaust holes 128a and the NH₃ gas exhausted from the second exhaust pipe 105 and the second exhaust holes 128b, it is possible to prevent a gas phase reaction by mixture of the DCS gas and the NH₃ gas.

When a silicon nitride layer having a predetermined thickness is formed after a predetermined period of time elapses, the valve 200c or the like is closed to stop the feed of the DCS and NH₃ gas.

(Vacuum Exhaustion Step): Nitrogen (N₂) as a carrier gas (inert gas), whose flow rate is controlled by the flow rate controller 202d which continues to open the valve 202c of the gas introduction port 136, is fed into the processing chamber 101. At this time, the first APC valve 204 of the first exhaust pipe 104 and the second APC valve 206 of the second exhaust pipe 105 are kept open. As a result, a residual gas is exhausted by the first exhaust pump 107 and the second exhaust pump 108, such that the internal pressure of the processing chamber 101 is set to be equal to or less than 20 Pa. Accordingly, the processing chamber 101 is filled with nitrogen (N₂).

(Wafer Export Step): By keeping the first APC valve 204 of the first exhaust pipe 104 and the second APC valve 206 of the second exhaust pipe 105 opened, the processing chamber 101 is returned to the same pressure as the exit side preliminary chamber 58 (for example, the atmospheric pressure). Then, the wafer 18 is processed in a reverse manner to the above-described process to be exported from the processing chamber 101.

According to this embodiment, the third gas feeding part interposed between the first exhaust part and the second exhaust part for feeding inert gas and at least one set of the gas feeding holes and gas exhaust holes are placed above the substrate loading surface of the substrate holder. Therefore, it is possible to prevent a mixture of the first processing gas fed from the first gas feeding part and the second processing gas fed from the second gas feeding part.

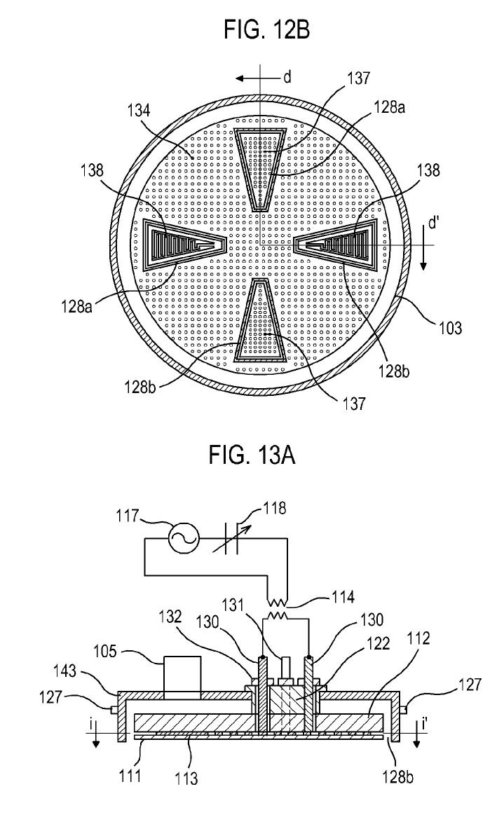

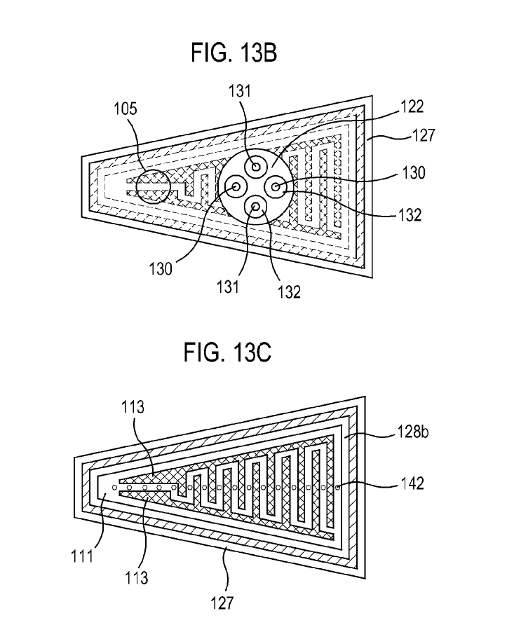

FIGS. 12 and 13 show a fifth embodiment of the present disclosure. This embodiment is different from the fourth embodiment in that NH₃ gas is plasmarized by a plasma source 138.

Specifically, while the NH₃ gas is activated by the remote plasma mechanism 212f in the substrate processing apparatus 100 according to the fourth embodiment, the NH₃ gas is plasmarized by the plasma source 138 provided within the processing chamber 101 in the substrate processing apparatus 100 according to the fifth embodiment.

The substrate processing apparatus 100 according to this embodiment will be described with reference to FIGS. 12A to 13C. In this embodiment, the same reference numerals as the fourth embodiment refer to the configuration with the same functions and therefore explanation thereof will not be repeated for the sake of clarity. FIG. 12A is a side sectional view of the substrate processing apparatus 100 according to this embodiment. FIG. 12B is a view observed in a direction indicated by an arrow c-c′ in FIG. 12A. FIG. 12A is a view observed in a direction indicated by an arrow d-d′ in FIG. 12B. FIGS. 13A to 13C are enlarged views of the plasma source 138.

(Plasma Generating Part): In this embodiment, as the second gas feeding part, the plasma source 138 is provided in place of the second shower head 137. In the plasma source 138, a conductive comb-shaped electrode structure 113 is interposed between a quartz plate 111 and a quartz block 112.

The comb-shaped electrode structure 113 is formed by engaging two interdigitally segmented electrodes with each other, in which high frequency powers whose phases are out of 180° are applied to both electrodes, respectively. One end of the power feeding terminals 130 is respectively connected to both ends of the comb-shaped electrode structure 113 and the other end of the power feeding terminals 130 is connected to a high frequency power supply 117 via an insulating transformer 114 and a matching transformer 118.

The NH₃ gas as the second processing gas is fed between the quartz plate 111 and the quartz block 112 from the gas introduction port 131. The fed NH₃ gas becomes plasma state by the comb-shaped electrode structure 113 and then is fed into the processing chamber 101 through a plurality of small holes 142 formed in the quartz plate 111.

The gas feeding pipe 212b is connected to the gas introduction port 131. The gas feeding pipe 212b is connected to the gas source 212e, the flow rate controller 212d and the valve 212c, which are arranged in order from the top. By performing a switching operation of the valve 212c, gas is fed or cut off from the gas feeding pipe 212b into the processing chamber 101.

An electrode cover 143 ventilated by the second exhaust pipe 105 is formed around the comb-shaped electrode structure 113 and the quartz block 112. A space is formed between the electrode cover 143 and the quartz block 112 to be utilized for the second exhaust holes 128b. The electrode cover 143 is air-tightly mounted on the reaction chamber wall 103 by a collar 127.

Connection points between the power feeding terminals 130, the gas introduction port 131 and the electrode cover 143 are air-tightened by an O-ring (not shown) formed in a sealing 132. In addition, an insulating block 122 to hold the quartz block 112 is air-tightly mounted on the electrode cover 143.

Next, as one step of a process of manufacturing a semiconductor device according to this embodiment which is performed by the above-described substrate processing apparatus 100, an example sequence of forming an insulating film on the wafer 18 will be described. As described below, operation of various components of the above-described substrate processing apparatus 100 is controlled by the controller 80.

The wafer import step and the pressure regulating step are performed in the same manner as in the fourth embodiment and therefore explanation thereof will not be repeated for the sake of clarity.

(Film Forming Step): While the rotating tray 120 is rotated, high frequency power is applied to the comb-shaped electrode structure 113. In addition, while the rotating tray 120 is rotated, the first process gas, i.e., the DCS gas, is fed from the first shower head 133 into the processing chamber 101.

In addition, the second processing gas, i.e., the ammonia (NH₃), is fed between the quartz plate 111 and the quartz block 112 from the gas introduction port 131. A flow rate of the ammonia gas is controlled by the flow rate controller 212d. The fed ammonia gas becomes plasma state by the high frequency power applied to the comb-shaped electrode structure 113. The ammonia plasma is generated on a surface of the quartz plate 111 (in the processing chamber 101 side).

Since the NH₃ gas has a high reaction temperature and hence has low reactivity under the above conditions including the temperature of the wafer and the internal pressure of the processing chamber, this embodiment generates radicals of the ammonia gas as well as ammonia ions through plasma excitation and uses the effects of these generated materials. Accordingly, the temperature of the wafer 18 may be set to have a range of low values as described above. When the ammonia gas is modified in the plasma state, it can have a high reaction with the DCS gas as compared to the radicals generated by the remote plasma mechanism in the fourth embodiment. On the other hand, such a high reaction requires suppression of mixture of the DCS gas and the NH₃ gas.

The NH₃ gas in the state of plasma reacts with a portion of the silicon containing layer as the first layer formed on the wafer 18 while it moves from below the first shower head 133 to below the second shower head 137. According to this reaction, the silicon containing layer is nitrified to be modified into a second layer containing silicon (the first element) and nitrogen (the second element), i.e., a silicon nitride layer (SiN layer). The process performed in this manner to form the silicon nitride layer when the wafer 18 passes below the first shower head 133 and the plasma source 138 is referred to as a silicon nitride layer forming process.

When the wafer 18 is rotated along with the rotating tray 120, the wafer 18 passes below the first shower head 133 and the plasma source 138 and subsequently passes below another first shower head 133 and another plasma source 138. In this manner, a silicon nitride layer can be formed with a predetermined thickness by repeating the silicon nitride layer forming process on the wafer 18.

Subsequently, a flow of gas to be fed will be described. The DCS gas fed from the first shower head 133 is exposed on the wafer 18 and then is exhausted from the first exhaust holes 128a along with the inert gas fed from the shower plate 134. In addition, the ammonia plasma fed from the plasma source 138 is exposed on the wafer 18 and then is exhausted from the second exhaust holes 128b along with the inert gas fed from the shower plate 134.

Since the inert gas fed from the shower plate 134 exists between the DCS gas exhausted from the first exhaust pipe 104 and the first exhaust holes 128a and the NH₃ gas exhausted from the second exhaust pipe 105 and the second exhaust holes 128b, it is possible to prevent a gas phase reaction by mixture of the DCS gas and the NH₃ gas.

When a silicon nitride layer having a predetermined thickness is formed after a predetermined period of time elapses, the valves 200c and 212c are closed to stop the feed of the DCS and NH₃ gas.

Although it has been illustrated in the fifth embodiment that the comb-shaped electrode structure 113 is employed as the plasma source 138, the present disclosure is not limited thereto but may employ an inductively coupled plasma (ICP) source for the plasma source 138.

In addition, although it has been illustrate in the fourth and fifth embodiments that the gas feeding surfaces of the shower heads (the first shower head 133 and the second shower head 137) has a trapezoidal shape, the present disclosure is not limited thereto but may have a triangular shape for the gas feeding surfaces or any other shape. In some embodiments, the gas feeding surfaces may be configured to have a structure where gas is increasingly fed in a direction from the shaft 121 to an edge of the rotating tray 120, in other words, in a direction away from the shaft 121.

In addition, although it has been illustrated in the fourth and fifth embodiments that the wafer 18 is held by the substrate holder 17, the present disclosure is not limited thereto. For example, a plurality of pins may hold the wafer 18, instead of the substrate holder 17.

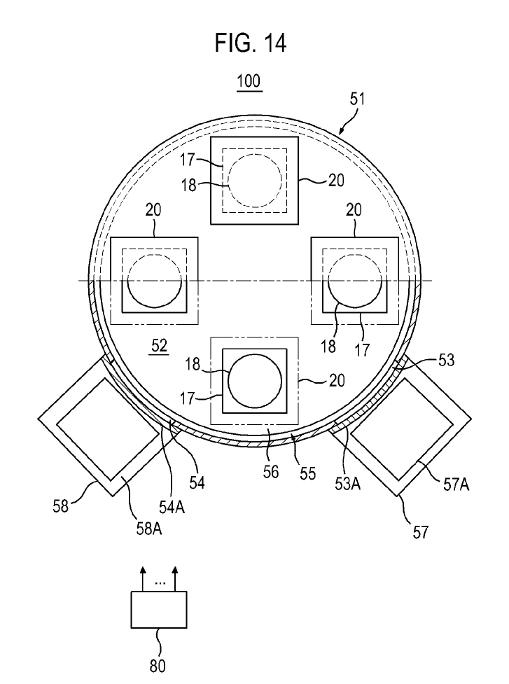

FIG. 14 shows a sixth embodiment of the present disclosure. This embodiment is different from the fourth embodiment in that the number of plasma generators 20 is four.

In the sixth embodiment, a movement base 55 as a moving device is horizontally placed on the substrate processing apparatus 100. That is, the movement base 55 includes a rotating tray 56 and is configured to revolve the substrate holder 17 (as a support member) holding the wafer 18 (as a moving or conveying object) by rotation of the tray 56.

The tray 56 has a diameter which is two times or more as large as an outer diameter of the wafer 18 and is set to be large enough to convey four wafers 18 in parallel with the same pitch, i.e., a 90° phase difference. As shown in FIG. 14, four plasma generators 20, each having a pair of electrodes, are arranged on the ceiling wall of the housing 51 with the same pitch, i.e., a 90° phase difference, in the rotation direction of the rotating tray 56. In addition, the plasma generator 20 may be replaced with the inductive coupling type device 20B (see FIG. 5).

Similar to other embodiments, this embodiment can improve manufacture yield. In addition, also in this embodiment, the wafer 18 can be uniformly processed for plasma process while the substrate holder 17 is being continuously moved by the movement base 55.

The present disclosure is not limited to the above embodiment but it should be understood that various modifications may be made without departing from the spirit and scope of the present disclosure.

For example, the plasma generator is not limited to the configuration employing the comb-shaped electrode pair and the inductive coupling type device but may be configured by an MMT apparatus or the like.

The number of plasma generators is not limited to four but may be one to three or more than five.

Although it has been illustrated in the above embodiments that the wafer 18 is subjected to the plasma process in the method of manufacturing a semiconductor device, the present disclosure is not limited thereto but may be applied to the general substrate processing apparatuses, performing plasma process on glass panels in a method of manufacturing LCDs, or other applications.

Next, a comparative example will be described.

A substrate processing apparatus 300 of a comparative example will be described with reference to FIGS. 15A to 17. The same reference numerals as the other embodiments refer to the configuration with the same functions and therefore explanation thereof will not be repeated for the sake of clarity.

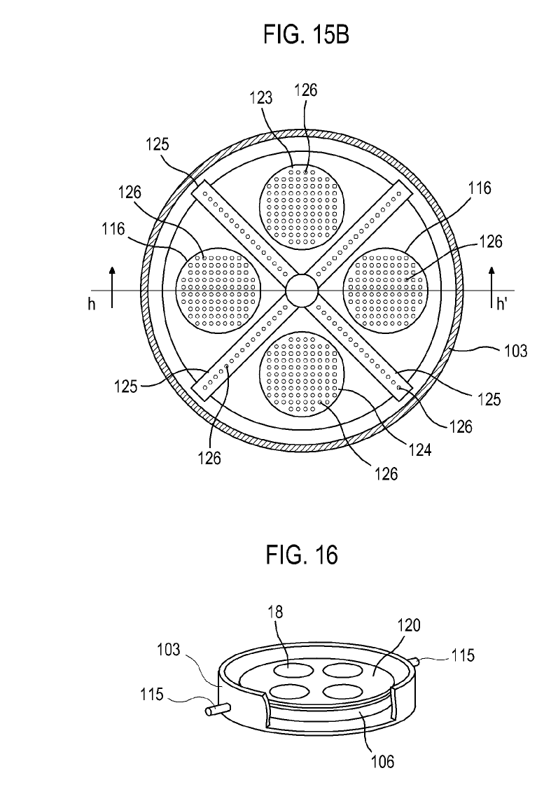

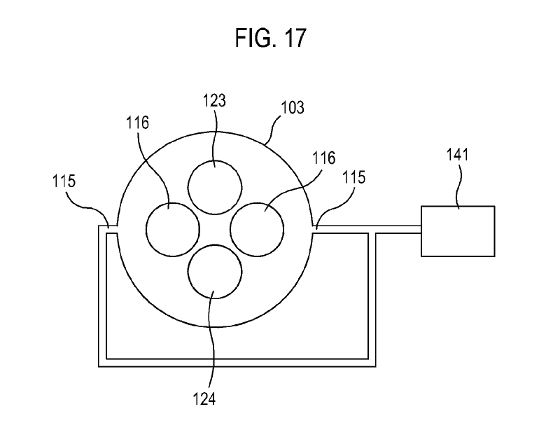

FIG. 15A is a side sectional view of the substrate processing apparatus 300 of this comparative example. FIG. 15B is a view observed in a direction indicated by an arrow g-g′ in FIG. 15A. FIG. 16 is an explanatory view for explaining a case where the wafers 18 are loaded. FIG. 17 is an explanatory view for explaining an exhaust part of the substrate processing apparatus 300 in the comparative example.

FIGS. 15A and 15B show sectional views of an apparatus for forming thin films on surfaces of a plurality of wafers 18 (four wafers in this example) loaded on the rotating tray 120 while rotating the wafers 18. FIG. 15B shows a top structure of the processing chamber 101 which is viewed from the rotating tray 120 in the arrow g-g′ direction. Also, FIG. 15A shows a section of the central portion of the processing chamber 101, including the rotating tray 120, the heater 106 and so on, which is viewed in the arrow h-h′ direction.

The processing chamber 101 is air-tightly sealed by the reaction chamber wall 103. Further, the heater 106 to heat the wafer 18 to be processed on the rotating tray 120 is disposed on the bottom of the processing chamber 101. The rotating tray 120 is rotatably mounted on the heater 106 and the rotation driver 119 is structured to rotate the shaft 121 connected to the rotating tray 120.

As shown in FIG. 16, the plurality of wafers 18 to be processed may be loaded on the rotating tray 120. In the top portion of the processing chamber 101, shower heads 123 and 124 for feeding a reactive gas are formed, where different gases may be showered from a plurality of gas discharge ports 126. Also, a pair of shower heads for feeding an inert gas is formed in the top portion of the processing chamber 101.

A partition block 125 is formed to partition the shower heads 123 and 124, and the inert gas is fed from gas discharge ports 126 formed in the partition block 125 such that a reactive gas is prevented from being mixed on the rotating tray 120 of the processing chamber 101.

In each shower head 123 and 124 is formed a gas feeding port 110 through which a required gas is fed into the processing chamber 101 via the shower heads 123 and 124.

FIG. 17 schematically shows a view of the processing chamber 101, which is observed in the arrow g-g′ direction, along with an exhaust part. In one side of the reaction chamber wall 103 is formed an exhaust pipe 115 through which a gas within the processing chamber 101 is exhausted from an exhauster 141 (see FIG. 17).

A gas feeding pipe 222b is connected to the gas introduction port 110. The gas feeding pipe 222b is connected to a gas source 222e, a flow rate controller 222d and a valve 222c, which are arranged in order from the top. By performing a switching operation of the valve 222c, a gas is fed or cut off from the gas feeding pipe 222b into the processing chamber 101.

Next, an example sequence of substrate process by the apparatus in the comparative example will be described. Here, as one example, an atomic layer deposition (ALD) process of forming nitride films one by one by alternately feeding dichlorosilane (DCS) and radicals of ammonia (NH₃) excited by remote plasma will be described.

Gas is exhausted from the processing chamber 101 by means of the exhauster 141 until the internal pressure of the processing chamber 101 reaches a predetermined value. The wafer 18 is loaded on the rotating tray 120 by means of a conveyance robot (not shown). In addition, power is applied to the heater 106 to heat the wafer 18 and the rotating tray 120 until the temperature thereof reaches 350° C.

Nitrogen is fed from the partition block 125 while rotating the rotating tray 120 having four wafers 18 loaded thereon at a rate of one revolution/sec. In this state, nitrogen is fed from two shower heads 116, a DCS gas is fed from the shower head 123, and a NH₃ gas excited by remote plasma is fed from the shower head 124.

Considering one wafer 18 loaded on the rotating tray 120, the wafer 18 is fed with dichlorosilane, nitrogen, ammonia radicals and nitrogen sequentially according to the rotation of the rotating tray 120. First, dichlorosilance molecules are absorbed on the wafer 18 by the feeding of dichlorosilane and then an excess of dichlorosilance is removed by the feeding of nitrogen.

In this state, ammonia radicals are fed to form one layer of nitride by a chemical reaction and an extra reaction product is purged from the next shower head. A series of gas feeding processes is repeated by the rotation of the rotating tray 120 to form nitride films one by one.

Since dichlorosilane and ammonia radicals are prevent from being mixed on the rotating tray 120 by the nitrogen fed from the partition block 125, thin films are deposited one by one without undergoing a gas phase reaction. However, dichlorosilane and ammonia radicals fed into the processing chamber 101 are mixed near the side of the reaction chamber wall 103 and are exhausted by the exhauster 141 via the exhaust pipe 115.

When dichlorosilane and ammonia radicals fed into the processing chamber 101 are mixed, they undergo a gas phase reaction to generate a reaction product. In the structure of this comparative example, although mixture of dichlorosilane and ammonia radicals in the vicinity of wafer 18 is prevented by the nitrogen fed from the partition block 125, they are mixed near the reaction chamber wall 103 and then are exhausted through the exhaust pipe 115. Accordingly, dichlorosilane and ammonia radicals undergo a gas phase reaction particularly near the exhaust pipe 115 of the reaction chamber wall 103 within the processing chamber 101 to generate a reaction by-product such as ammonium chloride or the like, which is adhered to the reaction chamber wall and an exhaust path. This ammonium chloride may be attributed to generation of alien substances, which requires frequent maintenance operations to remove them.

In addition, gases mixed in the exhauster 141 generate a reaction by-product such as ammonium chloride or the like, which may result in deterioration of pump performance. A reaction product may be adhered to the exhaust pipe 115 and the exhauster 141, and thus, in order to remove this reaction product or overhaul the exhauster 141, the operation of the apparatus needs to be frequently stopped, which may result in low operation rate and an increase in maintenance costs.

Hereinafter, preferred embodiments of the present disclosure will be appended.

According to one aspect of the present disclosure, there is provided a substrate processing apparatus including: a substrate support part provided within a process chamber and configured to support a substrate; a substrate support moving mechanism configured to move the substrate support part; a gas feeding part configured to feed a gas into the process chamber; an exhaust part configured to exhaust the gas within the process chamber; and a plasma generating part provided to face the substrate support part.

According to another aspect of the present disclosure, there is provided a substrate processing apparatus including: a substrate support part configured to load a substrate on a substrate loading surface and support the substrate; a substrate support moving mechanism configured to move the substrate support part; a first gas feeding part configured to feed a first gas from a first gas feeding hole; a first exhaust part configured to exhaust the first gas from a first exhaust hole; a second gas feeding part configured to feed a second gas from a second gas feeding hole; a second exhaust part configured to exhaust the second gas from a second exhaust hole; and a third gas feeding part interposed between the first exhaust part and the second exhaust part and configured to feed an inert gas, wherein at least one of a set of the first gas feeding hole and the first exhaust hole and a set of the second gas feeding hole and the second exhaust hole is arranged above the substrate loading surface with respect to the gravity direction.

Preferably in some embodiments, the first gas feeding hole, the first exhaust hole, the second gas feeding hole and the second exhaust hole are arranged to face the substrate loading surface.

Preferably in other embodiments, the substrate processing apparatus further includes: a first pump which is connected to the first exhaust part via a first exhaust path; and a second pump which is connected to the second exhaust part via a second exhaust path.

Preferably in alternate embodiments, the substrate support is configured to rotate around a shaft, and the first gas feeding part and the second gas feeding part are alternately arranged in a rotation direction of the shaft and are configured such that gas is increasingly fed in a direction away from the shaft.

According to still another aspect of the present disclosure, there is provided a method of manufacturing a semiconductor device using a substrate processing apparatus including: a substrate support part provided within a process chamber and configured to support a substrate; a substrate support moving mechanism configured to move the substrate support part; a gas feeding part configured to feed a gas into the process chamber; an exhaust part configured to exhaust the gas within the process chamber; and a plasma generating part disposed to face the substrate support part, the method including: exhausting the gas from the exhaust part while feeding the gas from the gas feeding part; and a moving the substrate support part to the gas feeding part and the exhaust part.

According to still another aspect of the present disclosure, there is provided a substrate processing apparatus including a process chamber configured to process a substrate; a support member configured to support the substrate; a movement device provided within the process chamber and configured to move a plurality of support members in a row with an interval; and a plasma generator disposed to face the movement device.

Preferably in some embodiments, a plurality of plasma generators is disposed with an interval in a direction in which the support member is moved.

According to still another aspect of the present disclosure, there is provided a substrate processing apparatus including a movement device provided within a process chamber and configured to process a substrate and move a plurality of support members configured to support the substrate in a concentric shape; and a plasma generator disposed to face the movement device.

What is claimed is:

1. A substrate processing apparatus comprising:
a substrate support part provided within a process chamber and configured to support a substrate;
a substrate support moving mechanism configured to move the substrate support part;
a gas feeding part configured to feed a gas into the process chamber;
an exhaust part configured to exhaust the gas within the process chamber; and
a plasma generating part disposed to face the substrate support part.

2. A substrate processing apparatus comprising:
a substrate support part configured to load a substrate on a substrate loading surface and support the substrate;
a substrate support moving mechanism configured to move the substrate support part;
a first gas feeding part configured to feed a first gas from a first gas feeding hole;
a first exhaust part configured to exhaust the first gas from a first exhaust hole;
a second gas feeding part configured to feed a second gas from a second gas feeding hole;
a second exhaust part configured to exhaust the second gas from a second exhaust hole; and
a third gas feeding part interposed between the first exhaust part and the second exhaust part and configured to feed an inert gas,
wherein at least one of a set of the first gas feeding hole and the first exhaust hole and a set of the second gas feeding hole and the second exhaust hole is arranged above the substrate loading surface with respect to the gravity direction.

3. The substrate processing apparatus according to claim 2,
wherein the first gas feeding hole, the first exhaust hole, the second gas feeding hole and the second exhaust hole are arranged to face the substrate loading surface.

4. The substrate processing apparatus according to claim 2, further comprising:
a first pump which is connected to the first exhaust part via a first exhaust path; and
a second pump which is connected to the second exhaust part via a second exhaust path.

5. The substrate processing apparatus according to claim 2,
wherein the substrate support part is rotated around a shaft, and
wherein the first gas feeding part and the second gas feeding part are alternately arranged in a rotation direction of the shaft and are configured such that a gas is increasingly fed in a direction away from the shaft.

6. A method of manufacturing a semiconductor device using a substrate processing apparatus including:
a substrate support part provided within a process chamber and configured to support a substrate;
a substrate support moving mechanism configured to move the substrate support part;
a gas feeding part configured to feed a gas into the process chamber;
an exhaust part configured to exhaust the gas within the process chamber; and
a plasma generating part disposed to face the substrate support part, the method comprising:
exhausting the gas from the exhaust part while feeding the gas from the gas feeding part; and
moving the substrate support part to the gas feeding part and the gas exhaust part.
